(19) United States
(12) Patent Application Publication
(10) Pub. No.: US 2026/0338833 A1
(43) Pub. Date: Oct. 29, 2026

(54) BATTERY IDENTIFICATION METHOD

(71) Applicant: TOYOTA JIDOSHA KABUSHIKI KAISHA, Toyota-shi Aichi-ken (JP)

(72) Inventor: Seiichi SHIMIZU, Toyota-shi Aichi-ken (JP)

(73) Assignee: TOYOTA JIDOSHA KABUSHIKI KAISHA, Toyota-shi Aichi-ken (JP)

(21) Appl. No.: 19/653,602

(22) Filed: Apr. 21, 2026

(30) Foreign Application Priority Data
Apr. 23, 2025 (JP) 2025-071887

(51) Int. Cl. G01R 19/00; G01K 1/02; G01K 7/22

(52) U.S. Cl. CPC G01R 19/0038; G01K 1/026; G01K 7/22

(57) ABSTRACT

A battery identification method is performed on a battery module during manufacturing of a battery pack and includes: measuring a voltage of a temperature measurement circuit configured to measure a temperature of a busbar provided on the battery module in a state where no current is flowing through the busbar at a time of mounting the battery module in a case of the battery pack; estimating an internal resistance of a thermistor connected to the temperature measurement circuit based on the measured voltage; calculating the voltage of the temperature measurement circuit based on the estimated internal resistance and a resistance of a discrimination resistor provided in the temperature measurement circuit; and determining whether the battery module is a genuine product by comparing the calculated voltage with the measured voltage.

### CROSS-REFERENCE TO RELATED APPLICATIONS

The present application claims priority to and incorporates by reference the entire contents of Japanese Patent Application No. 2025-071887 filed in Japan on Apr. 23, 2025.

### BACKGROUND

The present disclosure relates to a battery identification method.

JP 2012-085470A discloses a monitoring unit that monitors whether a battery module containing multiple battery cells is a genuine product. This monitoring unit determines whether the battery module is genuine based on identification information stored in the battery module's memory.

### SUMMARY

In the configuration described in JP 2012-085470A, during battery pack manufacturing, the battery module is assembled into the battery pack case. Registration of the identification information by the monitoring unit occurs only after communication is established between the monitoring unit and the storage unit. Therefore, if a non-genuine battery module is mistakenly connected during the initial connection between the battery module and the monitoring unit, the monitoring unit cannot determine that the battery module is non-genuine. Furthermore, a memory circuit storing information indicating that the battery module is genuine must be provided for each battery module, increasing costs.

There is a need for a battery identification method that suppresses cost while enabling detection during battery pack manufacturing of incorrect assembly of battery modules of different types.

According to one aspect of the present disclosure, there is provided a battery identification method performed on a battery module during manufacturing of a battery pack, the method including: measuring a voltage of a temperature measurement circuit configured to measure a temperature of a busbar provided on the battery module in a state where no current is flowing through the busbar at a time of mounting the battery module in a case of the battery pack; estimating an internal resistance of a thermistor connected to the temperature measurement circuit based on the measured voltage; calculating the voltage of the temperature measurement circuit based on the estimated internal resistance and a resistance of a discrimination resistor provided in the temperature measurement circuit; and determining whether the battery module is a genuine product by comparing the calculated voltage with the measured voltage.

### BRIEF DESCRIPTION OF THE DRAWINGS

FIG. 1 is a schematic diagram showing a battery module in an embodiment;

FIG. 2 is a diagram for explaining the temperature measurement circuit;

FIG. 3 is a diagram for explaining the battery ECU and circuit configuration;

FIG. 4 is a flowchart diagram showing the battery identification flow; and

FIG. 5 is a diagram for explaining the battery ECU and circuit configuration in a modified example.

### DETAILED DESCRIPTION

The battery identification method in the embodiments of the present disclosure will now be described in detail. Note that the present disclosure is not limited to the embodiments described below.

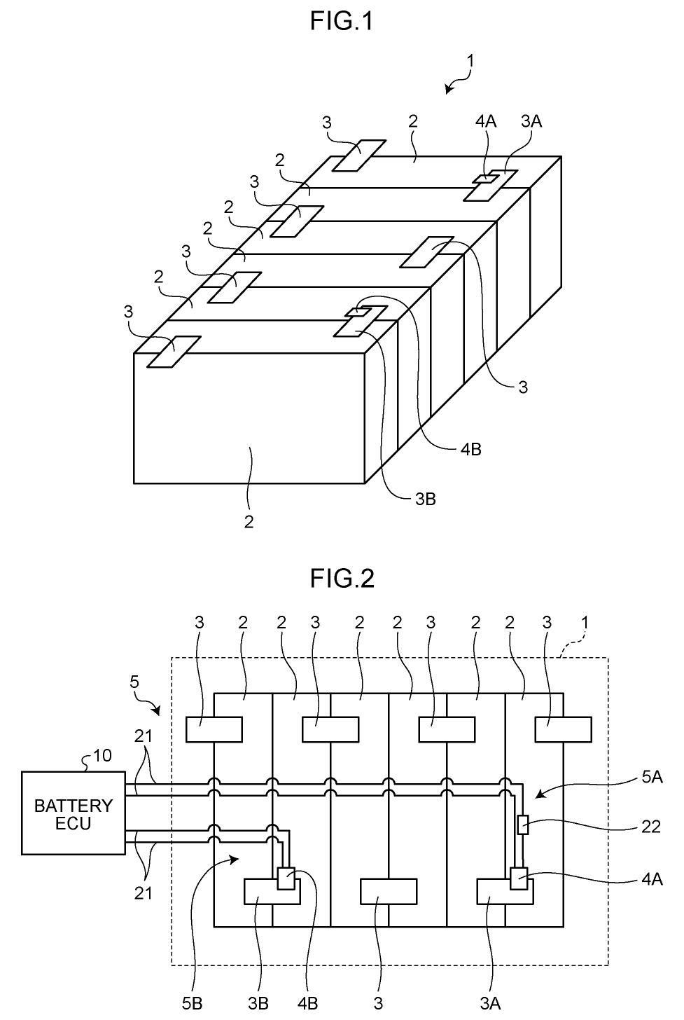

FIG. 1 is a schematic diagram showing a battery module in an embodiment. The battery module 1 is the subject for identifying the type of battery. The battery module 1 is included in a battery pack. The battery pack is installed in battery electric vehicles and hybrid electric vehicles.

The battery module 1 includes a plurality of battery cells 2, a plurality of busbars 3, and two thermistors 4.

The battery cell 2 is a prismatic cell. The battery cell 2 is composed of a lithium-ion secondary battery. Within battery module 1, multiple battery cells 2 are arranged in a row in a first direction. Battery module 1 has a stacked structure where multiple battery cells 2 are stacked in the first direction. Battery cells 2 adjacent to each other in the first direction are electrically connected by bus bars 3. Battery module 1 is a battery pack where multiple battery cells 2 are electrically connected in series by multiple bus bars 3.

The busbar 3 is a metal member connected to the terminals of the battery cell 2. For example, the busbar 3 is composed of a copper plate. The busbar 3 connects the terminals of adjacent battery cells 2, electrically connecting the adjacent battery cells 2.

Thermistor 4 is an NTC thermistor that measures the temperature of busbar 3. Thermistor 4 is a busbar thermistor provided on busbar 3, measuring the temperature of busbar 3 heated by the current flowing through it.

In one battery module 1, thermistors 4 are provided on any two of the multiple busbars 3.

As illustrated in FIG. 2, the plural bus bars 3 include a first bus bar 3A and a second bus bar 3B. The two thermistors 4 include a first thermistor 4A provided on the first bus bar 3A and a second thermistor 4B provided on the second bus bar 3B.

The battery module 1 is controlled by the battery ECU 10.

The battery electronic control unit (ECU) 10 is an electronic control unit that controls the battery module 1. The battery ECU 10 includes a processor and memory. The battery ECU 10 loads a program stored in a storage unit into the working area of the memory and executes it. By controlling various components through program execution, it achieves functions corresponding to predetermined purposes. Signals from various sensors are input to the battery ECU 10. Signals from a voltage sensor detecting the voltage of the battery cell 2, signals from a temperature sensor detecting the temperature of the battery cell 2, and signals from the thermistor 4 are input to the battery ECU 10. The thermistor 4 is connected to the battery ECU 10 via the wire harness 21. The battery ECU 10 executes battery control based on signals input from various sensors. The battery ECU 10 measures the voltage of battery cell 2, the temperature of battery cell 2, and the temperature of busbar 3, and controls battery module 1 based on this information.

The battery ECU 10 is connected to a temperature measurement circuit 5 that measures the temperature of the busbar 3. The temperature measurement circuit 5 measures the temperature of the busbar 3 at two or more measurement points on different busbars 3, which connect the battery cells 2 to each other. In the example illustrated in FIG. 2, the temperature measurement circuit 5 includes a first temperature measurement circuit 5A that measures the temperature of the first busbar 3A and a second temperature measurement circuit 5B that measures the temperature of the second busbar 3B. The first thermistor 4A is connected to the first temperature measurement circuit 5A. The second thermistor 4B is connected to the second temperature measurement circuit 5B.

The battery ECU 10 is connected to one of the two thermistors 4 via a discrimination resistor 22. In the embodiment, the battery ECU 10 is connected to the first thermistor 4A via the discrimination resistor 22. The discrimination resistor 22 is provided in the first temperature measurement circuit 5A.

The identification resistor 22 is a resistor for identifying the battery type. The identification resistor 22 has a resistance value determined by the type of battery cell 2. The resistance value of the identification resistor 22 is predetermined based on the type of battery cell 2. Since the constant of the identification resistor 22 affects the measurement results of the thermistor 4, it is set to a constant within a range that does not cause an effect. The wire harness 21 connects the thermistor 4 to the battery ECU 10, connects the thermistor 4 to the identification resistor 22, and connects the identification resistor 22 to the battery ECU 10.

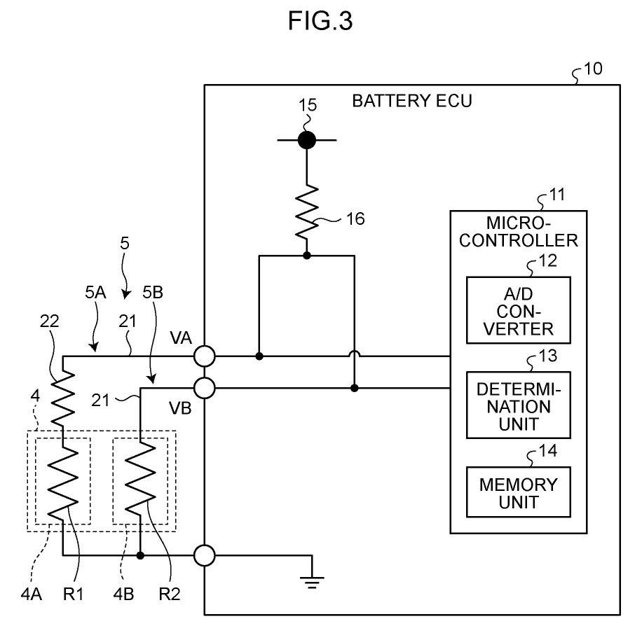

As illustrated in FIG. 3, the battery ECU 10 includes a microcontroller 11.

The microcontroller 11 includes an A/D converter 12, a judgment unit 13, and a memory unit 14. The microcontroller 11 processes, judges, and stores input signals. The microcontroller 11 measures and judges the voltage of the battery cell 2, the temperature of the battery cell 2, the temperature of the busbar 3, and the state of the discrimination signal. The A/D converter 12 converts analog data related to the bus bar 3 temperature into digital data. The decision unit 13 makes decisions based on the digital signals. The memory unit 14 stores information.

The battery ECU 10 includes a power supply 15 and a pull-up resistor 16. Power supply 15 is a power source for thermistor measurement. Pull-up resistor 16 is a resistor for fixing the signal state. Power supply 15 is connected to an auxiliary battery installed in an electric vehicle equipped with a battery pack. Pull-up resistor 16 is connected to power supply 15. Microcontroller 11 is connected to power supply 15 via pull-up resistor 16.

The microcontroller 11 operates using power supplied from the power supply 15. The microcontroller 11 is connected to the temperature measurement circuit 5 and measures the voltage of the temperature measurement circuit 5. The microcontroller 11 measures the first voltage VA, which is the voltage of the first temperature measurement circuit 5A, and measures the second voltage VB, which is the voltage of the second temperature measurement circuit 5B.

At a manufacturing plant producing battery packs, battery packs containing battery modules of different types from battery module 1 may be manufactured. For example, even if battery cells have the same external shape as battery cell 2, multiple types of battery cells with different internal physical properties from battery cell 2 may exist as standard battery cells handled at this manufacturing plant. In this case, the manufacturing plant produces multiple types of battery modules that have the same external shape as battery module 1 but exhibit different charging and discharging characteristics due to differing physical properties of the battery cells.

Furthermore, since the control conditions required for safe use of the battery module differ when the physical properties of the battery cells change, it is necessary to execute control appropriate for the battery cells in the product state. Therefore, it is desirable to be able to determine whether a battery module is a genuine product during battery pack manufacturing. Accordingly, the battery identification method in the embodiment is configured to detect when a battery module of a different type from battery module 1 is mistakenly assembled during the battery pack manufacturing process.

The battery identification method of the embodiment is a simplified method that determines whether the battery is the correct one anticipated by the battery ECU 10 based on the resistance value of the identification resistor 22. While prior art provided dedicated memory circuits for battery identification within the battery module, the embodiment eliminates the need for such memory circuits. This enables simplification of identification signals and reduction in the number of terminals, thereby suppressing costs. Furthermore, it may detect potential battery module installation errors that may occur during the manufacturing process.

Specifically, at least two thermistors 4 for measuring busbar temperature are provided on a single battery module 1. A discrimination resistor 22 for identifying the battery type is placed between one of these thermistors 4 and the battery ECU 10.

The battery ECU 10 determines whether the battery is the intended type or a different type by measuring the resistance value of the identification resistor 22. If the battery is different from the intended type, the battery ECU 10 may disable the battery module. Although the identification resistor 22 may potentially affect the measurement results of the thermistor 4, placing the identification resistor 22 in the temperature measurement circuit 5 used to determine whether the temperature exceeds a threshold allows its impact on the control to be minimized.

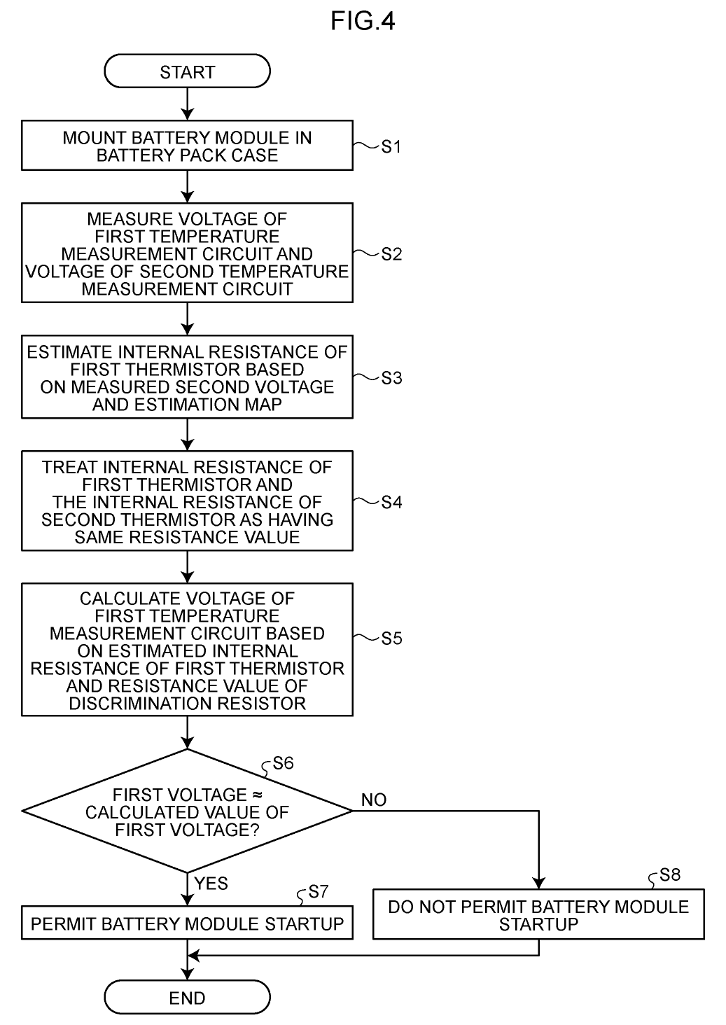

FIG. 4 is a flowchart illustrating a battery identification flow. The battery identification flow illustrated in FIG. 4 is performed during battery pack manufacturing.

During the battery pack manufacturing process, the battery module 1 is mounted into the battery pack case (Step S1). The battery pack manufacturing method includes a mounting process. Step S1 is the mounting process. The mounting process involves installing the battery module 1 into the lower case of the battery pack. The battery pack case includes an upper cover and a lower case. In step S1, the battery module 1 is mounted inside the lower case.

In the measurement step included in the battery identification method, power is supplied to the microcontroller 11 while no current is flowing through the bus bar 3 included in the battery module 1, and the voltage of the temperature measurement circuit 5 is measured (step S2). In step S2, with the battery ECU 10 connected to the thermistor 4 via the wire harness 21 and no current flowing through the bus bar 3, the microcontroller 11 is powered by the auxiliary battery and measures the voltage of the temperature measurement circuit 5. At this time, the microcontroller 11 measures the first voltage VA and the second voltage VB as the voltage of the temperature measurement circuit 5.

In the estimation step included in the battery identification method, the resistance value R1 of the internal resistance of the first thermistor 4A is estimated based on the measured value of the second voltage Vb and the estimation map (Step S3). The estimation map used in step S3 is a map stored in memory unit 14, showing the relationship between the voltage Vb of the second temperature measurement circuit 5B and the resistance value of the internal resistance R1 of the first thermistor 4A. In step S3, microcontroller 11 calculates an estimated value for the resistance value of the internal resistance R1 based on the measured value of the second voltage Vb and the estimation map stored in memory unit 14.

Since no current flows through the bus bar 3 during the battery discrimination method, the microcontroller 11 treats the internal resistance R1 of the first thermistor 4A and the internal resistance R2 of the second thermistor 4B as having the same resistance value (Step S4). When no current flows through the busbar 3 of the battery module 1, the difference between the resistance value of the internal resistance R1 of the first thermistor 4A and the resistance value of the internal resistance R2 of the second thermistor 4B falls within an error range.

In the calculation step included in the battery identification method, the first voltage VA of the first temperature measurement circuit 5A is calculated based on the resistance value of the identification resistor 22 mounted on the correct battery module 1 and the estimated value of the internal resistance R1 (Step S5). In Step S5, the microcontroller 11 obtains the calculated value of the first voltage VA. The microcontroller 11 calculates the first voltage VA using the sum of the resistance value of the discrimination resistor 22 and the estimated value of the internal resistance R1.

In the determination step included in the battery discrimination method, it is determined whether the calculated value of the first voltage VA is equivalent to the measured value of the first voltage VA (Step S6). In step S6, the microcontroller 11 compares the calculated value of the first voltage VA with the measured value of the first voltage VA and determines whether the installed battery module 1 is a genuine product. For example, it is determined whether the calculated value of the first voltage VA is the same as the measured value of the first voltage VA.

If it is determined that the calculated value of the first voltage VA and the measured value of the first voltage VA are equivalent (Step S6: Yes), the microcontroller 11 judges that a correct battery module 1 is installed and permits the battery module 1 to start up (Step S7). When the processing of Step S7 is performed, this battery identification flow ends.

If it is determined that the calculated value of the first voltage VA is not equivalent to the measured value of the first voltage VA (Step S6: No), the microcontroller 11 determines that the correct battery module 1 is not installed and does not permit the activation of the battery module 1 (Step S8). When the processing of Step S8 is executed, this battery determination flow ends.

As described above, according to the embodiment, it is sufficient to provide a discrimination resistor 22 between the thermistor 4 measuring the temperature of the busbar 3 and the battery ECU 10, without increasing the number of wires in the wire harness 21. Therefore, it is possible to discriminate the battery type for the battery module 1 while suppressing cost.

Moreover, the configuration may include multiple temperature measurement circuits 5 connected to the battery ECU 10, and the number of temperature measurement circuits 5 is not limited to two. The number of temperature measurement circuits 5 may be two or more, and the identification resistor 22 may be provided in any one of these temperature measurement circuits 5.

As a variant, it is also possible to determine the battery type using a simple tool separate from the battery ECU 10.

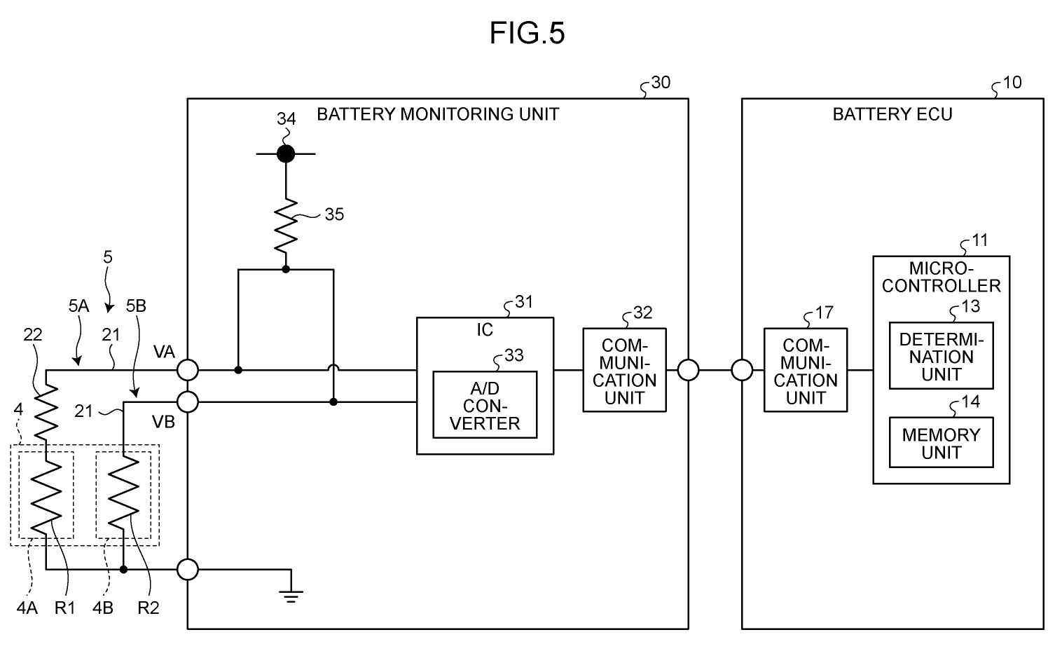

For example, as illustrated in FIG. 5, the battery state is measured using a battery monitoring unit 30 equipped with an IC 31 that measures the battery state, instead of the battery ECU 10. The battery monitoring unit 30 includes an IC 31 and a communication section 32. The IC 31 includes an A/D conversion section 33. The communication section 32 communicates with the battery ECU 10.

The battery monitoring unit 30 is configured to communicate with the battery ECU 10. Furthermore, the battery monitoring unit 30 includes a power supply 34 and a pull-up resistor 35. The battery ECU 10 includes a microcontroller 11 and a communication unit 17. The microcontroller 11 includes a determination unit 13 and a memory unit 14. The communication unit 17 communicates with the battery monitoring unit 30.

The battery monitoring unit 30 measures the battery's state and transmits the measurement results to the battery ECU 10. The battery ECU 10 determines whether the battery module 1 is genuine based on the information transmitted from the battery monitoring unit 30.

The present disclosure enables the detection of incorrectly assembled battery modules of different types during battery pack manufacturing while suppressing costs.

Although the disclosure has been described with respect to the specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A battery identification method performed on a battery module during manufacturing of a battery pack, the method comprising:
measuring a voltage of a temperature measurement circuit configured to measure a temperature of a bus bar provided on the battery module in a state where no current is flowing through the busbar at a time of mounting the battery module in a case of the battery pack;
estimating an internal resistance of a thermistor connected to the temperature measurement circuit based on the measured voltage;
calculating the voltage of the temperature measurement circuit based on the estimated internal resistance and a resistance of a discrimination resistor provided in the temperature measurement circuit; and
determining whether the battery module is a genuine product by comparing the calculated voltage with the measured voltage.

2. The battery identification method according to claim 1, wherein the estimating includes estimating the internal resistance based on the measured voltage and a map showing a relationship between the voltage and the internal resistance.

3. The battery identification method according to claim 2, wherein
the bus bar include a first bus bar and a second bus bar,
the thermistor includes a first thermistor provided on the first bus bar and a second thermistor provided on the second bus bar,
the temperature measurement circuit includes
a first temperature measurement circuit to which the first thermistor is connected, and
a second temperature measurement circuit connected to the second thermistor,
the discrimination resistor is provided in the first temperature measurement circuit,
the map shows a relationship between: a second voltage which is a voltage of the second temperature measurement circuit; and an internal resistance of the first thermistor,
the measuring includes measuring the second voltage and a first voltage which is a voltage of the first temperature measurement circuit,
the estimating includes estimating the internal resistance of the first thermistor based on the measured second voltage and the map,
the calculating includes calculating the first voltage based on the estimated internal resistance of the first thermistor and the resistance of the discrimination resistor, and
determining includes determining whether the battery module is a genuine product by comparing the calculated first voltage with the measured first voltage.
